(19) United States
(12) Patent Application Publication
(10) Pub. No.: US 2013/0025923 A1
(43) Pub. Date: Jan. 31, 2013

(54) COMPONENT WITH PINS AND FIXED ON CIRCUIT BOARD

(71) Applicant: Yung-Cheng CHANG, Taoyuan Shien (TW)

(72) Inventor: Yung-Cheng CHANG, Taoyuan Shien (TW)

(21) Appl. No.: 13/237,728

(22) Filed: Sep. 20, 2011

(30) Foreign Application Priority Data
Jul. 27, 2011 (TW) 100126527

(51) Int. Cl. H05K 1/16

(52) U.S. Cl. 174/260

(57) ABSTRACT

A component fixed on a circuit board. The circuit board has a first perforation and a second perforation. The component has a body, a first pin, and a second pin. The first pin is connected to a side of the body. The first pin has a first section, a first bent section, and a second bent section. The first bent section is stuck in the first perforation. The second pin is connected to another side of the body. The second pin has a second section, a third bent section, and a fourth bent section. The third bent section is stuck in the second perforation. The design prevents the body from toppling and makes it stable and convenient to assemble the component onto the circuit board.

### BACKGROUND

1. Technical Field

The present invention relates to a component fixed on a circuit board, and more particularly, to a component with fins and fixed on a circuit board.

2. Related Art

A circuit board is a board that holds and interconnects several components. Examples of the components include active electronic components, passive electronic components, and heat slugs that cool the electronic components. The circuit board is an insulation body laid with circuit lines that interconnect the electronic components and allows the electronic components to function and process signals. To fix the components on the circuit board, the manufacturer solders the pins of the components onto the circuit board directly.

FIG. 1 shows a combination between a conventional passive component 10a and a circuit board 30a. Two parallel upright pins 20a are connected to two sides at the bottom of the passive component 10a. The circuit board 30a has a placing surface 40a and a soldering surface 50a and a plurality of fixation holes 60a. The passive component 10a is placed on the placing surface 40a and the upright pins 20a pass through the fixation holes 60a. Please refer to FIG. 2. The end of the upright pins 20a that extend out from the fixation holes 60a are bent so as to fix the passive component 10a on the circuit board 30a. Then, the upright pins 20 are soldered to the soldering surface 50a of the circuit board 30a. Through the circuit board 30a, the passive component 10a is electrically connected to other electronic components.

Because the passive component 10a stands on the circuit board 30a with only the upright pins 20a, the passive component 10a may topple to the right or left. To prevent the passive component 10a from toppling and as a result affecting the assembly process, the assembly worker must let the soldering surface 50a of the circuit board 30a face up, place the passive component 10a onto the circuit board 30a from the down-facing placing surface 40a, adjust the position of the passive component 10a beneath the circuit board 30a, bend the upright pins 20a above the circuit board 30a, and solder the upright pins 20a to fix the passive component 10a. The overall process is inconvenient, difficult, and time-consuming for the assembly worker because the worker must adjust the position of the passive component 10a beneath the circuit board 30a and bend the upright pins 20a above the circuit board 30a.

### BRIEF SUMMARY

The present invention provides a component with fins and fixed on a circuit board. Some of the objectives of the present invention are to prevent a body of the component from toppling and to make it stable and convenient to assemble the component with the circuit board.

The present invention provides a component with fins and fixed on a circuit board. The circuit board has a first perforation and a second perforation. The component has a body, a first pin, and a second pin. The first pin is connected to a side of the body. The first pin has a first section, a first bent section, and a second bent section. The first bent section is stuck in the first perforation. The second pin is connected to another side of the body. The second pin has a second section, a third bent section, and a fourth bent section. The third bent section is stuck in the second perforation.

The present invention allows the component to be positioned firmly through simply plugging the pins of the component into the circuit board. The body won't topple or leave the circuit board easily. It's easy and not time-consuming for an assembly worker to do the assembly work. The stability and convenience of assembly is also increased. Furthermore, the present invention allows the soldering process to be omitted, hence prevents the component from being damaged by high temperature. Even if there is a soldering process, because the first bent section and the third bent section are stuck on the circuit board, it's easy to carry out the soldering process.

It is to be understood that both the foregoing general description and the following detailed description are exemplary and explanatory only and are not restrictive of the invention, as claimed.

### BRIEF DESCRIPTION OF THE DRAWINGS

FIG. 1 and FIG. 2 show combinations of a conventional component and a circuit board.

FIG. 3 shows a 3-dimensional diagram of a component according to a first embodiment of the present invention.

FIG. 4 shows a 3-dimensional diagram of the component in combination according to the first embodiment of the present invention.

FIG. 5 and FIG. 6 show sectional diagrams of the component according to the first embodiment of the present invention.

FIG. 7 and FIG. 8 show the component in combination according to the first embodiment of the present invention.

FIG. 9 shows a 3-dimensional diagram of a component according to a second embodiment of the present invention.

FIG. 10 shows a sectional diagram of the component according to the second embodiment of the present invention.

FIG. 11 shows a 3-dimensional diagram of a component according to a third embodiment of the present invention.

FIG. 12 shows a 3-dimensional diagram of the component in combination according to the third embodiment of the present invention.

FIG. 13 and FIG. 14 show sectional diagrams of the component according to the third embodiment of the present invention.

FIG. 15 shows a sectional diagram of a component according to a fourth embodiment of the present invention.

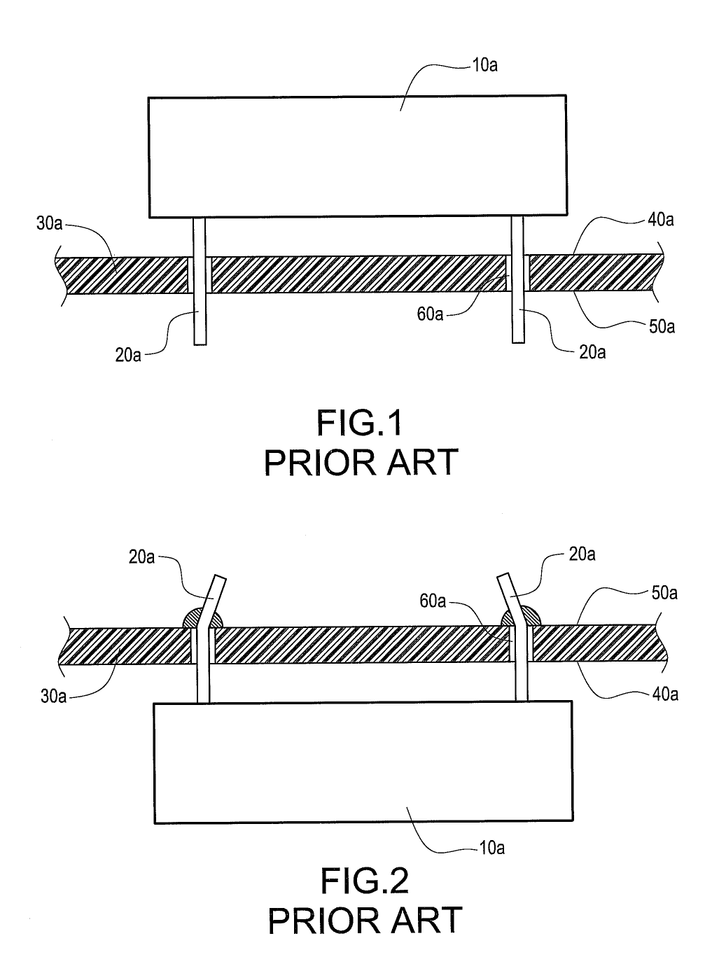

### DETAILED DESCRIPTION

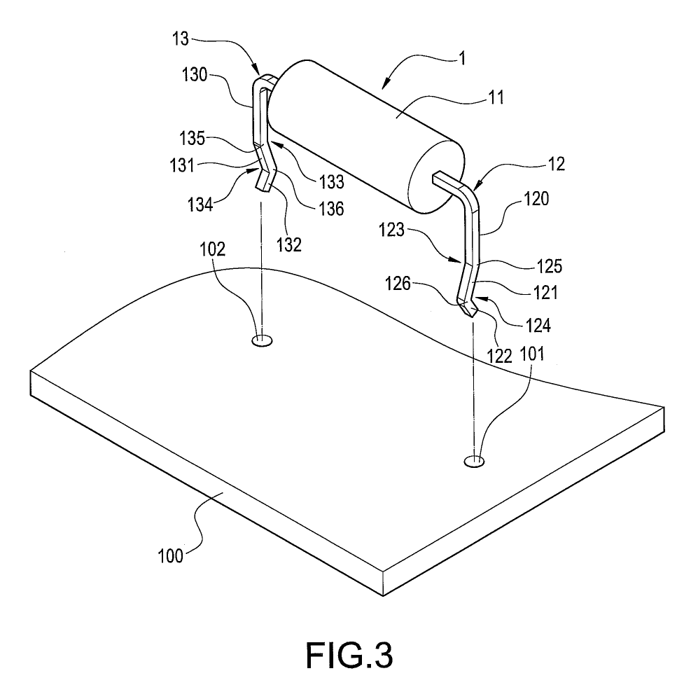

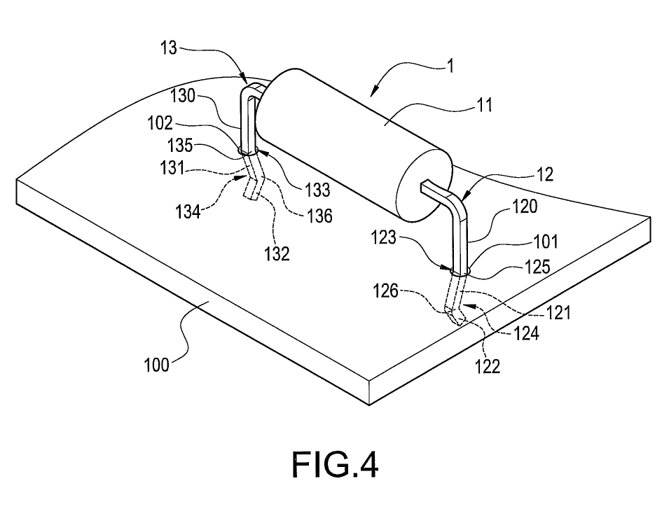

Please refer to FIG. 3 to FIG. 6. An embodiment of the present invention provides a component with pins to be fixed on a circuit board. The circuit board 100 has a first perforation 101 and a second perforation 102. The first perforation 101 and the second perforation 102 both have an upright inner wall 103 and a bottom rim 104.

The component 1 in this embodiment is a passive component, such as a resistor, a capacitor, or an inductor. FIG. 3 shows a component according to a first embodiment of the present invention. For example, the component with pins in this embodiment is a resistor. The component with pins mainly includes a body 11, a first pin 12, and a second pin 13.

The first pin 12 is connected to a side of the body 11. The first pin 12 has a first section 120, a first bent section 121, and a second bent section 122. The first section 120 and the first bent section 121 form a first opening 123. The first bent section 121 and the second bent section 122 form a second opening 124. The opening direction of the first opening 123 and the opening direction of the second opening 124 are opposite. The first bent section 121 corresponds to, passes through, and engages with the first perforation 101.

The second pin 13 is connected to another side of the body 11. The second pin 13 has a second section 130, a third bent section 131, and a fourth bent section 132. The second section 130 and the third bent section 131 form a third opening 133. The third bent section 131 and the fourth bent section 132 form a fourth opening 134. The opening direction of the third opening 133 and the opening direction of the fourth opening 134 are opposite. The third bent section 131 corresponds to, passes through, and engages with the second perforation 102.

More specifically, the first opening 123 has a first angle θ₁; the second opening 124 has a second angle θ₂; the third opening 133 has a third angle θ₃; the fourth opening 134 has a fourth angle θ₄. The first angle θ₁, the second angle θ₂, the third angle θ₃, and the fourth angle θ₄ are all between 90 degrees and 180 degrees. The opening direction of the first opening 123 and the opening direction of the second opening 124 are opposite; the opening direction of the third opening 133 and the opening direction of the fourth opening 134 are opposite; the opening direction of the first opening 123 and the opening direction of the third opening 133 are opposite; the opening direction of the second opening 124 and the opening direction of the fourth opening 134 are opposite.

Furthermore, the first section 120 and the first bent section 121 interconnect at a first upper turning point 125; the first bent section 121 and the second bent section 122 interconnect at a first lower turning point 126. The first upper turning point 125 contacts the upright inner wall 103. The first lower turning point 126 engages with the bottom rim 104 of the upright inner wall 103. The second section 130 and the third bent section 131 interconnect at a second upper turning point 135; the third bent section 131 and the fourth bent section 132 interconnect at a second lower turning point 136. The second upper turning point 135 contacts the upright inner wall 103. The second lower turning point 136 engages with the bottom rim 104 of the upright inner wall 103. In addition, the first pin 12 and the second pin 13 can be riveted or soldered to the body 11.

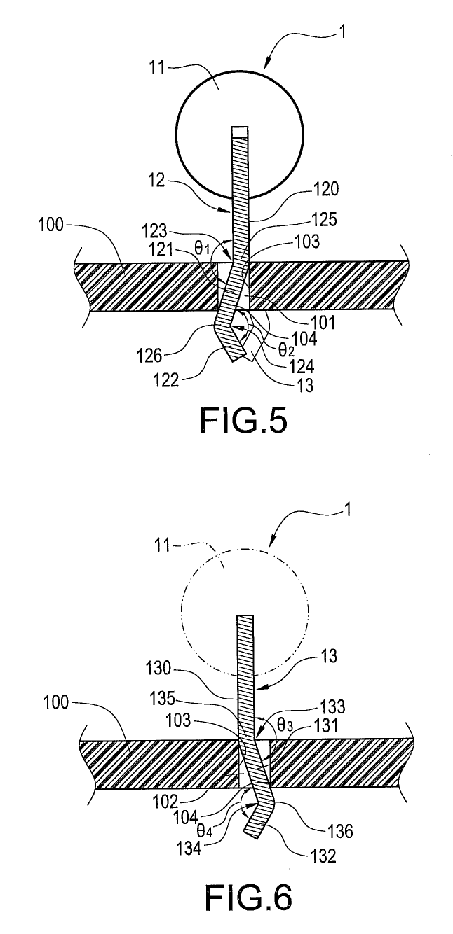

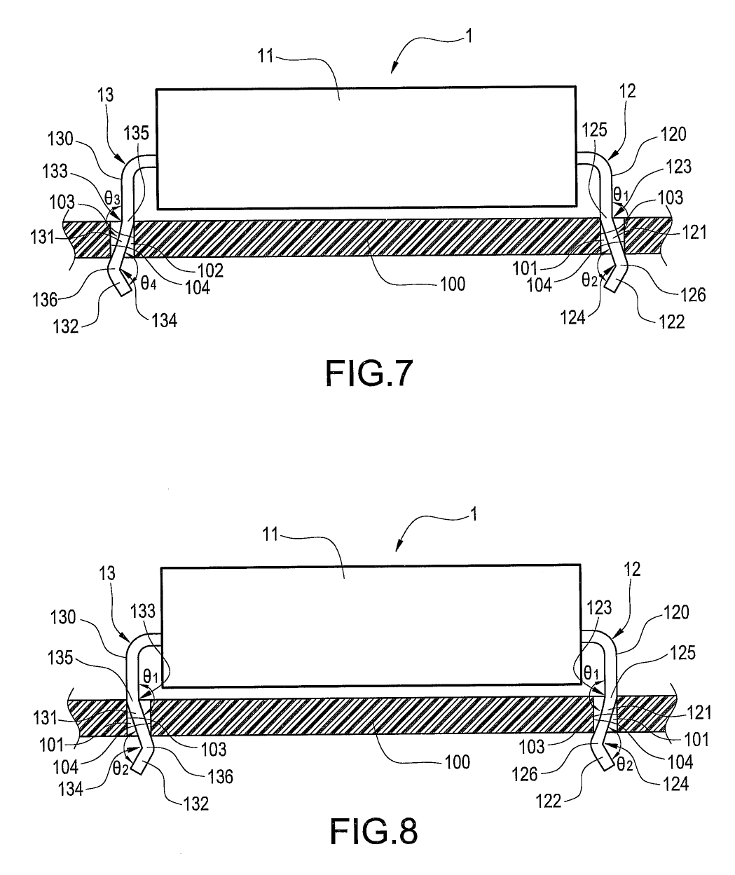

Please refer to FIG. 5 to FIG. 8, which show the combination between the component of this embodiment and the circuit board. The first pin 12 and the second pin 13 are connected to two sides of the body 11, respectively. The first pin 12 and the second pin 13 have the first bent section 121 and the third bent section 131, respectively; where the first bent section 121 and the third bent section 131 are bent towards opposite directions. The first section 120 and the second bent section 122 extend from the top and bottom of the first bent section 121, respectively. The second section 130 and the fourth bent section 132 extend from the top and bottom of the third bent section 131, respectively. The second bent section 122 and the fourth bent section 132 are bent towards opposite directions. The first section 120 and the first bent section 121 interconnect at the first upper turning point 125. The first bent section 121 and the second bent section 122 interconnect at the first lower turning point 126. The second section 130 and the third bent section 131 interconnect at the second upper turning point 135. The third bent section 131 and the fourth bent section 132 interconnect at the second lower turning point 136. The first upper turning point 125 contacts the upright inner wall 103; the first lower turning point 126 engages with the bottom rim 104 of the upright inner wall 103. The second upper turning point 135 contacts the upright inner wall 103; the second lower turning point 136 engages with the bottom rim 104 of the upright inner wall 103. The overall structure allows the first bent section 121 and the third bent section 131 to be wedged in the first perforation 101 and the second perforation 102, respectively. As a result, the body 11 is securely fixed on the circuit board 100.

FIG. 5 shows the first bent section 121 being wedged in the first perforation 101. Because the first upper turning point 125 contacts the upright inner wall 103, the upright inner wall 103 will apply pressure on the first bent section 121, causing the first bent section 121 to deform. In response, the first bent section 121 will have a restoring force, causing the first bent section 121 to be stuck elastically on the circuit board 100 through the first perforation 101. Furthermore, as shown in the figure, the first lower turning point 126 and the bottom rim 104 are at the left side of the first pin 12. When the body 11 shifts to the right, the first lower turning point 126 and the bottom rim 104 will engage with each other, preventing the body 11 from toppling to the right. Furthermore, if the body 11 is pulled due to some reasons and the first lower turning point 126 slides into the first perforation 101, the second bent section 122 and the bottom rim 104 will engage with each other. This will keep the first pin 12 in the first perforation 101, preventing the body 11 from leaving the circuit board 100 or deviating from its original position. Similarly, as shown in FIG. 6, the third bent section 131 is stuck on the circuit board 100 elastically through the second perforation 102. As shown in the figure, the second lower turning point 136 and the bottom rim 104 are at the right side of the second pin 13, preventing the body 11 from toppling to the left. Furthermore, if the body 11 is pulled due to some reasons and the second lower turning point 136 slides into the second perforation 102, the fourth bent section 132 and the bottom rim 104 will engage with each other. This will keep the second pin 13 in the second perforation 102, preventing the body 11 from leaving the circuit board 100 or deviating from its original position.

As shown in FIG. 6, the first pin 12 and the second pin 13 are connected to two sides of the body 11, respectively. Through the first bent section 121 and the third bent section 131, the two sides of the body 11 are stuck to the upright inner walls 103 of the first perforation 101 and the second perforation 102, respectively. In addition, the first pin 12 and the second pin 13 have the first bent section 121 and the third bent section 131 of opposite directions. This can prevent the body 11 from toppling to the right or left. Furthermore, the second bent section 122 and the fourth bent section 132 extends from the first pin 12 and the second pin 13, respectively. This prevents the body 11 from leaving the circuit board 100 or deviating from its original position even when it is pulled due to some reasons. As a result, as long as the component with pins is plugged onto the circuit board 100, the component will stay in the position and will not leave the circuit board 100 or deviate from its position easily. Therefore, the embodiment makes it easy, convenient, and not time-consuming to assemble a component onto a circuit board.

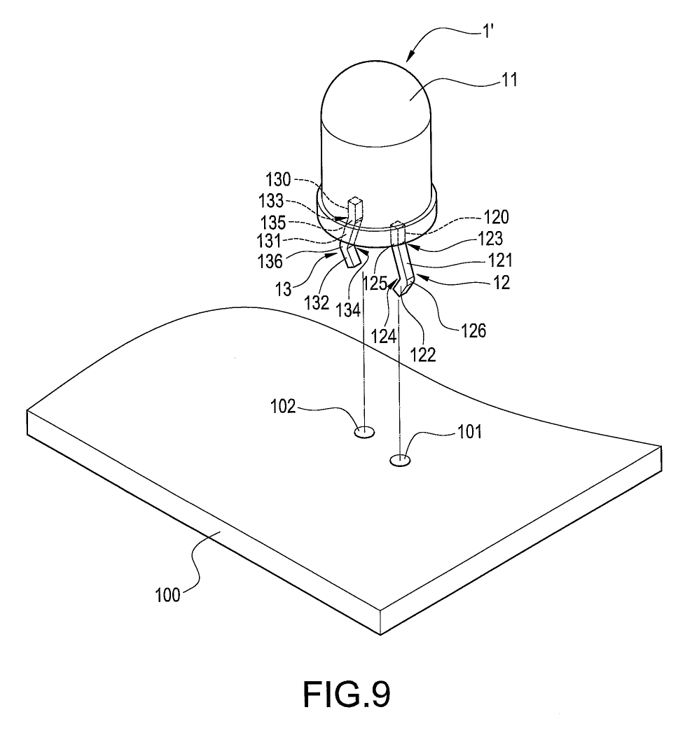

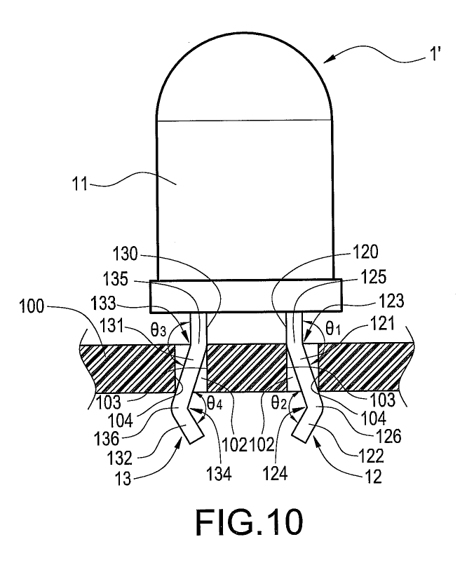

Please refer to FIG. 9 and FIG. 10, which illustrate a component according to a second embodiment of the present invention. In this embodiment, the component with pins is an active component 1′, such as a diode, a light emitting diode (LED), a transistor, or an integrated circuit (IC). The component shown in FIG. 9 is an LED. A first pin 12 and a second pin 13 are connected to the two sides of the body 11 of the active component P. As long as the two sides of the body 11 are stuck to the upright inner walls 103 of the first perforation 101 and the second perforation 102 through the first bent section 121 and the third bent section 131, respectively, the component 1′ is stably positioned on the circuit board 100. The first pin 12 and the second pin 13 have a first bent section 121 and a third bent section 131 of opposite directions, respectively. This prevents the body 11 from toppling to the right or left. Furthermore, a second bent section 122 and a fourth bent section 132 extend from the first pin 12 and the second pin 13, respectively. This prevents the body 11 from leaving the circuit board 100 or deviating from its original position when being pulled. Therefore, the embodiment makes it easy, convenient, and not time-consuming to assemble a component onto a circuit board. Furthermore, if the active component 1′ is a component that cannot sustain high temperature, such as an LED or a transistor, it might be damaged when the circuit board 100 is sent in a soldering furnace. Because the embodiment allows the component 1′ to be fixed onto the circuit board 100 through the first pin 12 and the second pin 13 without any soldering process, the embodiment can prevent the component 1′ from being damaged by the high temperature in a soldering furnace.

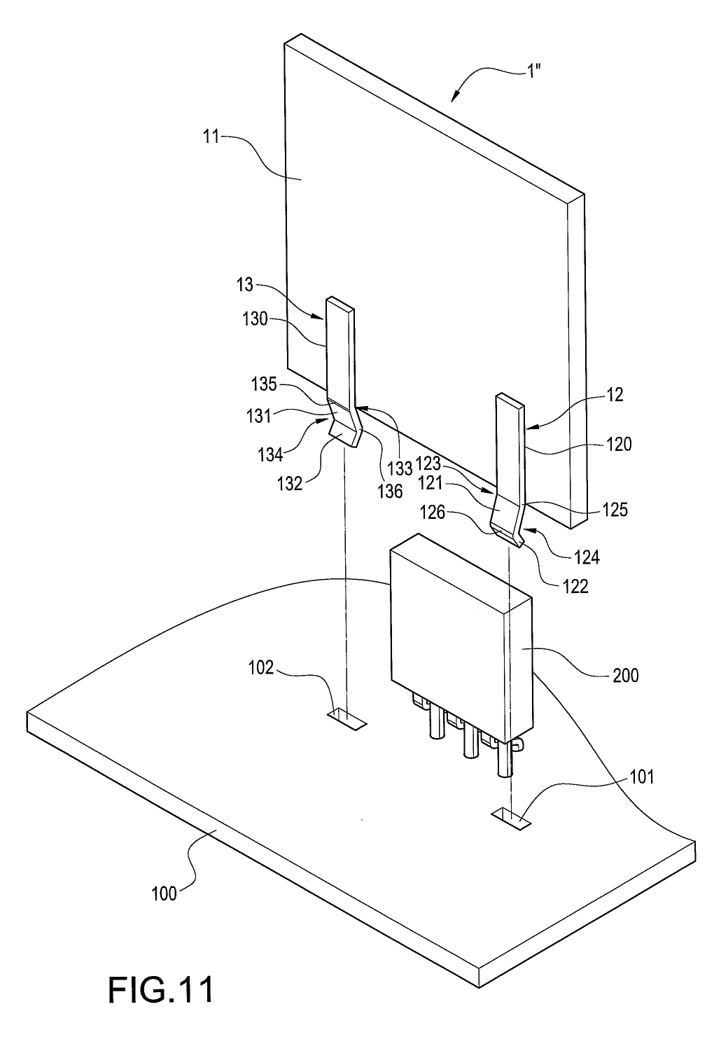

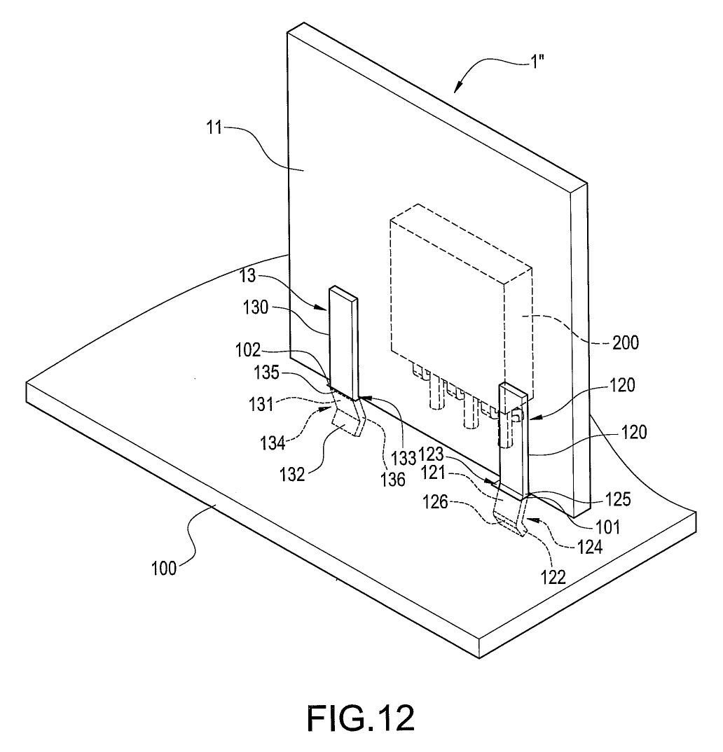

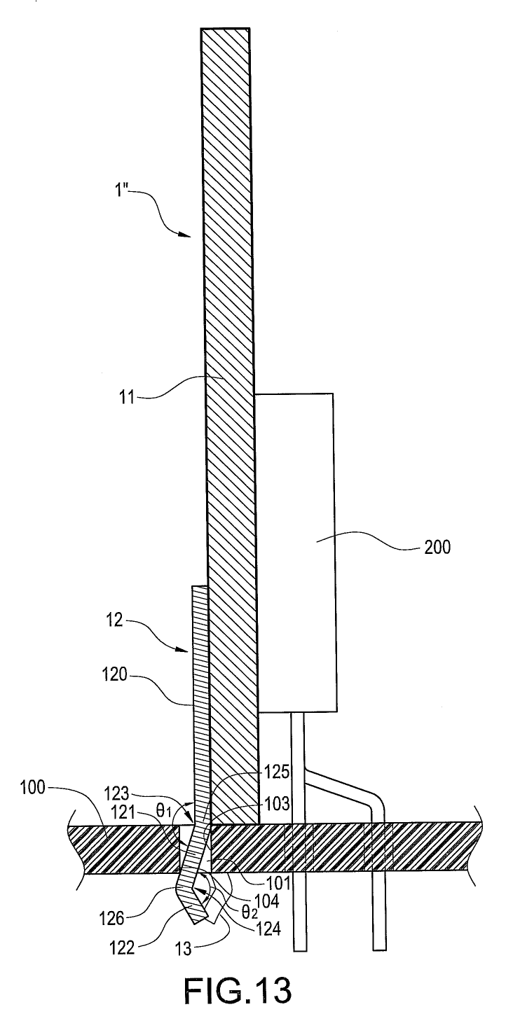

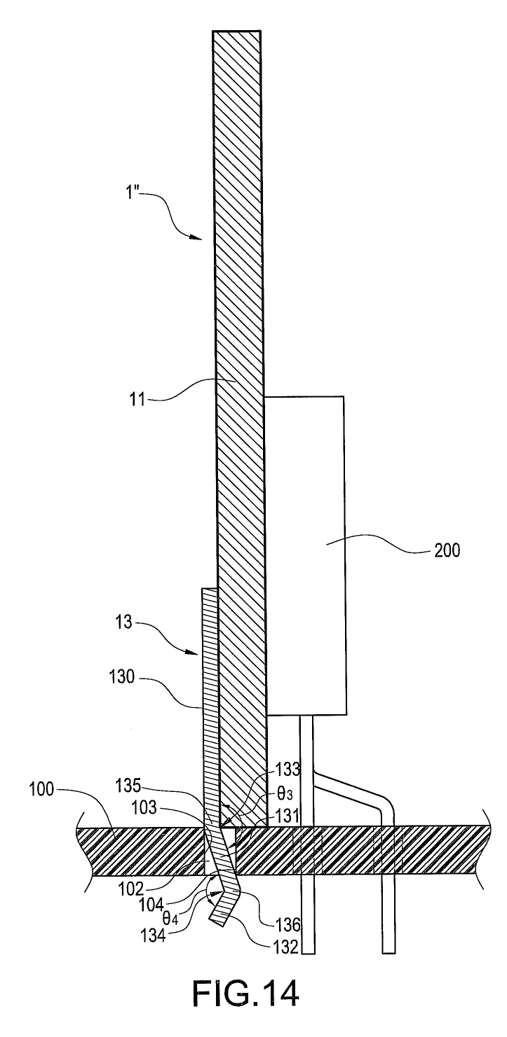

Please refer to FIG. 11 to FIG. 14, which show a component with pins according to a third embodiment of the present invention. In this embodiment, the component with pins is a heat slug 1″. A surface of a body 11 of the heat slug contacts an electronic component 200 to absorb heat generated by the electronic component 200. The other surface of the body 11 of the heat slug 1″ is connected to a first pin 12 and a second pin 13. The first pin 12 and the second pin 13 have a first bent section 121 and a third bent section 131 of opposite directions. The first pin 12 and the second pin 13 give the component of this embodiment characters similar to those of the components of the previous embodiments.

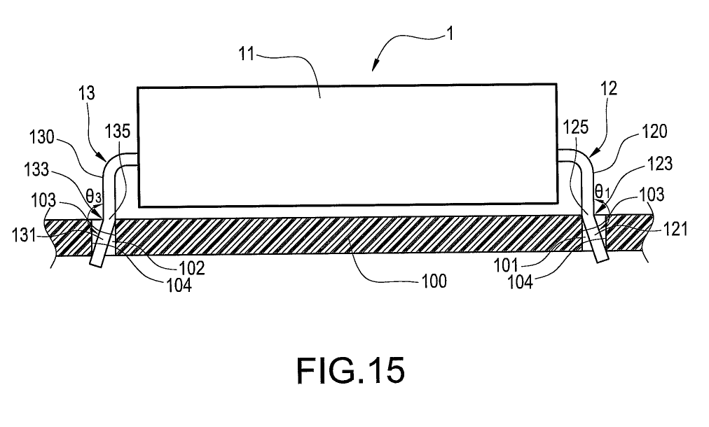

Please refer to FIG. 15, which shows a component with pins according to a fourth embodiment of the present invention. In this embodiment, a first pin 12 and a second pin 13 are connected to two sides of a body 11 of the component 1. The first pin 12 has a first section 120 and a first bent section 121. The first section 120 and the first bent section 121 form a first opening 123. The second pin 13 has a second section 130 and a third bent section 131. The second section 130 and the third bent section 131 form a third opening 133. The first opening 123 has a first angle θ₁ and the third opening 133 has a third angle θ₃. Both the first angle θ₁ and the third angle θ₃ are between 90 degrees and 180 degrees. The opening direction of the first opening 123 and the opening direction of the third opening 133 are opposite. The first bent section 121 is stuck in the first perforation 101; the third bent section 131 is stuck in the second perforation 102.

The first section 120 and the first bent section 121 interconnect at a first upper turning point 125. The second section 130 and the third bent section 131 interconnect at a second upper turning point 135. The first upper turning point 125 contacts the upright inner wall 103. The end of the first bent section 121 engages with the bottom rim 104 of the upright inner wall 103. The second upper turning point 135 contacts the upright inner wall 103. The end of the third bent section 131 engages with the bottom rim 104 of the upright inner wall 103. The upright inner walls 103 press and deform the first bent section 121 and the third bent section 131, causing the first bent section 121 and the third bent section 131 to have restoring forces. The restoring forces cause the two sides of the body 11 to be stuck to the upright inner walls 103 of the first perforation 101 and second perforation 102 through the first bent section 121 and the third bent section 131. Therefore, the component 1 is stably positioned on the circuit board 100. The design of this embodiment prevents the body 11 from toppling to the right or left. Furthermore, the embodiment makes it easy, convenient, and not time-consuming to assemble the component 1 onto the circuit board 100. The assembly procedure is therefore more stable.

The above description is given by way of example, and not limitation. Given the above disclosure, one skilled in the art could devise variations that are within the scope and spirit of the invention disclosed herein. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A component fixed on a circuit board, the circuit board having a first perforation and a second perforation, the component comprises:
a body;
a first pin, connected to a side of the body, the first pin having a first section, a first bent section, and a second bent section, the first bent section being stuck in the first perforation; and
a second pin, connected to another side of the body, the second pin having a second section, a third bent section, and a fourth bent section, the third bent section being stuck in the second perforation.

2. The component of claim 1, wherein the first section and the first bent section form a first opening with a first angle, the first bent section and the second bent section form a second opening with a second angle, the second section and the third bent section form a third opening with a third angle, the third bent section and the fourth bent section form a fourth opening of a fourth angle.

3. The component of claim 2, wherein the first angle, the second angle, the third angle, and the fourth angle are all between 90 degrees and 180 degrees.

4. The component of claim 3, wherein the opening direction of the first opening is opposite to the opening direction of the second opening, and the opening direction of the third opening is opposite to the opening direction of the fourth opening.

5. The component of claim 4, wherein the opening direction of the first opening is opposite to the opening direction of the third opening, and the opening direction of the second opening is opposite to the opening direction of the fourth opening.

6. The component of claim 1, wherein the upper portion of the first bent section contacts the inner wall of the first perforation, and the lower portion of the first bent section engages with the bottom rim of the inner wall of the first perforation.

7. The component of claim 6, wherein the upper portion of the third bent section contacts the inner wall of the second perforation, and the lower portion of the third bent section engages with the bottom rim of the inner wall of the second perforation.

8. A component fixed on a circuit board, the circuit board having a first perforation and a second perforation, the component comprising:
a body;
a first pin, connected to a side of the body, the first pin having a first section and a first bent section, the first bent section being stuck in the first perforation; and
a second pin, connected to another side of the body, the second pin having a second section and a third bent section, the third bent section being stuck in the second perforation.

9. The component of claim 8, wherein the first section and the first bent section form a first opening with a first angle, and the second section and the third bent section form a third opening with a third angle.

10. The component of claim 9, wherein the opening direction of the first opening is opposite to the opening direction of the third opening.

11. The component of claim 8, wherein the upper portion of the first bent section contacts the inner wall of the first perforation, and the lower portion of the first bent section engages with the bottom rim of the inner wall of the first perforation.

12. The component of claim 8, wherein the upper portion of the third bent section contacts the inner wall of the second perforation, and the lower portion of the third bent section engages with the bottom rim of the inner wall of the second perforation.
